(19) United States
(12) Patent Application Publication
(10) Pub. No.: US 2025/0204174 A1
(43) Pub. Date: Jun. 19, 2025

(54) DISPLAY APPARATUS AND DEVICE USING THE SAME

(71) Applicant: CANON KABUSHIKI KAISHA, Tokyo (JP)

(72) Inventors: MASAHIKO SONE, Tokyo (JP); TOSHIYUKI OGAWA, Chiba (JP)

(21) Appl. No.: 18/979,371

(22) Filed: Dec. 12, 2024

(30) Foreign Application Priority Data
Dec. 13, 2023 (JP) 2023-209996

(51) Int. Cl. H10K 59/124; H10K 59/131

(52) U.S. Cl. CPC H10K 59/124; H10K 59/131

(57) ABSTRACT

A display apparatus in which a display region and a peripheral region disposed near the display region are disposed on a substrate. The display region includes at least a metal layer, an insulating layer, a lower electrode, a light-emitting layer, and an upper electrode in this order from the substrate side. The peripheral region includes at least a peripheral metal layer and a peripheral insulating layer in this order from the substrate side. A first region that isolates the metal layer from the peripheral metal layer is disposed between the metal layer and the peripheral metal layer in a plan view with respect to the substrate. A width of the first region is less than or equal to twice a film thickness of the peripheral insulating layer in a cross-section passing through the substrate, the display region, and the peripheral region.

### BACKGROUND

### Field

The present disclosure relates to a display apparatus and a device using the same.

### Description of the Related Art

Some recent organic electroluminescence (EL) elements (hereinafter also referred to as “organic EL elements”, “organic light-emitting elements”, “display apparatuses”, or “organic devices”) have an optical resonator structure. In an organic device having an optical resonator structure, light emitted from the organic device passes through an anode and the transmitted light is reflected on a reflection layer. The light emitted from the organic device and the reflected light interfere with each other and intensify each other, thereby enhancing the light emission efficiency of the organic device. Japanese Patent Application Laid-Open No. 2021-72282 (PTL 1) discusses a display apparatus having an optical resonator structure.

PTL 1 does not discuss a layout of a reflection layer related to a region between a display region and a peripheral region in the display apparatus. Accordingly, in the region between the display region and the peripheral region, an upper electrode film is prone to thinning. In other words, in the display apparatus discussed in PTL 1, the resistance of the upper electrode tends to increase.

### SUMMARY

The present disclosure has been made in view of the above-described issue, and is directed to reducing an increase in the resistance of an upper electrode.

According to some embodiments, a display apparatus includes a substrate, a display region on the substrate, and a peripheral region near the display region on the substrate, wherein the display region includes at least a metal layer, an insulating layer, a lower electrode, a light-emitting layer, and an upper electrode in this order from a substrate side, wherein the peripheral region includes at least a peripheral metal layer and a peripheral insulating layer in this order from the substrate side, wherein a first region that isolates the metal layer from the peripheral metal layer is disposed between the metal layer and the peripheral metal layer in a plan view with respect to the substrate, and wherein a width of the first region is less than or equal to twice a film thickness of the peripheral insulating layer in a cross-section passing through the substrate, the display region, and the peripheral region.

Further features of the present disclosure will become apparent from the following description of exemplary embodiments with reference to the attached drawings.

### BRIEF DESCRIPTION OF THE DRAWINGS

FIGS. 1A and 1B are plan views each illustrating a display apparatus according to a first exemplary embodiment.

FIGS. 2A and 2B are sectional views each illustrating the display apparatus according to the first exemplary embodiment.

FIGS. 3A to 3C are plan views each illustrating a display apparatus according to a second exemplary embodiment.

FIGS. 4A to 4D are plan views each illustrating a display apparatus according to a third exemplary embodiment.

FIG. 5 is a schematic view illustrating an example of a display apparatus according to an exemplary embodiment of the present invention.

FIG. 6A is a schematic view illustrating an example of an image capturing apparatus according to an exemplary embodiment of the present invention, and FIG. 6B is a schematic view illustrating an example of an electronic apparatus according to an exemplary embodiment of the present invention.

FIG. 7A is a schematic view illustrating an example of a display apparatus according to an exemplary embodiment of the present invention, and FIG. 7B is a schematic view illustrating an example of a foldable display apparatus.

FIG. 8A is a schematic view illustrating an example of an illumination apparatus according to an exemplary embodiment of the present invention, and FIG. 8B is a schematic view illustrating an example of an automobile including a vehicle lighting tool according to an exemplary embodiment of the present invention.

FIG. 9A is a schematic view illustrating an example of a wearable device according to an exemplary embodiment of the present invention, and FIG. 9B is a schematic view illustrating a configuration example of the wearable device including an image capturing apparatus according to an exemplary embodiment of the present invention.

FIG. 10A is a schematic view illustrating an example of an image forming apparatus according to an exemplary embodiment of the present invention, FIG. 10B is a schematic view illustrating an example of an exposure light source of the image forming apparatus according to an exemplary embodiment of the present invention, and FIG. 10C is a schematic view illustrating an example of the exposure light source of the image forming apparatus according to an exemplary embodiment of the present invention.

### DESCRIPTION OF THE EMBODIMENTS

Various exemplary embodiments, features, and aspects of the present invention will be described in detail below with reference to the attached drawings. The following exemplary embodiments are not intended to limit the scope of the claimed invention. Although multiple features are described in the exemplary embodiments, not all of the features are essential to the invention, and the features may be combined in any way. Furthermore, in the attached drawings, the same reference numerals are given to the same or similar configurations, and redundant description thereof is omitted.

In the present specification, a specific one of a plurality of pixels 201 is referred to as, for example, a pixel 201 “r” with a reference numeral followed by a subscript. A pixel that can be any of the pixels 201 is simply referred to as a pixel “201”. This also applies to other components.

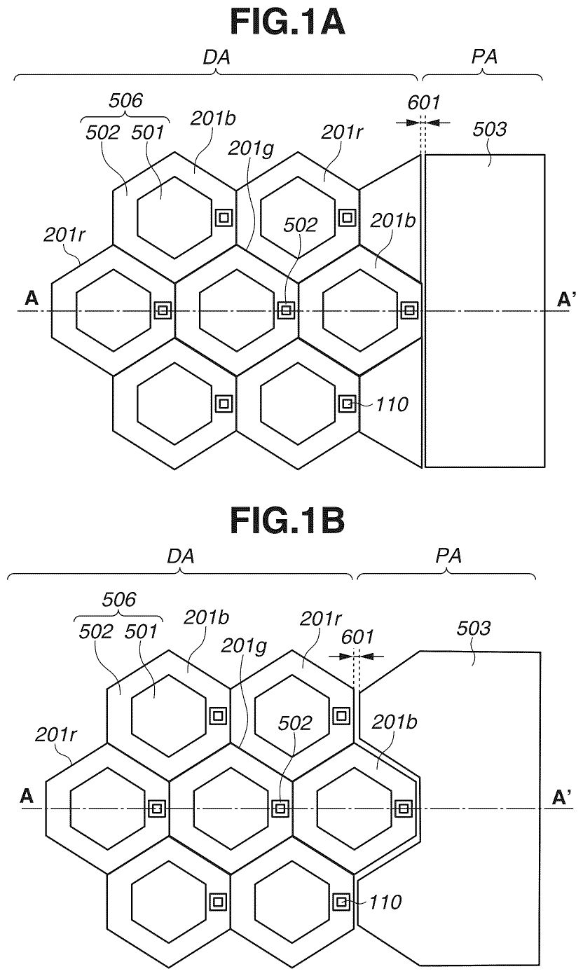

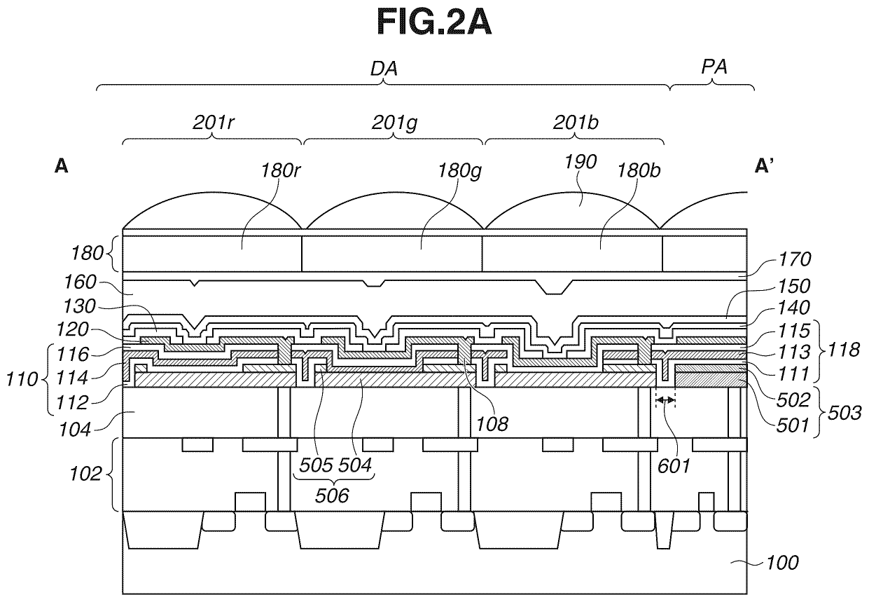

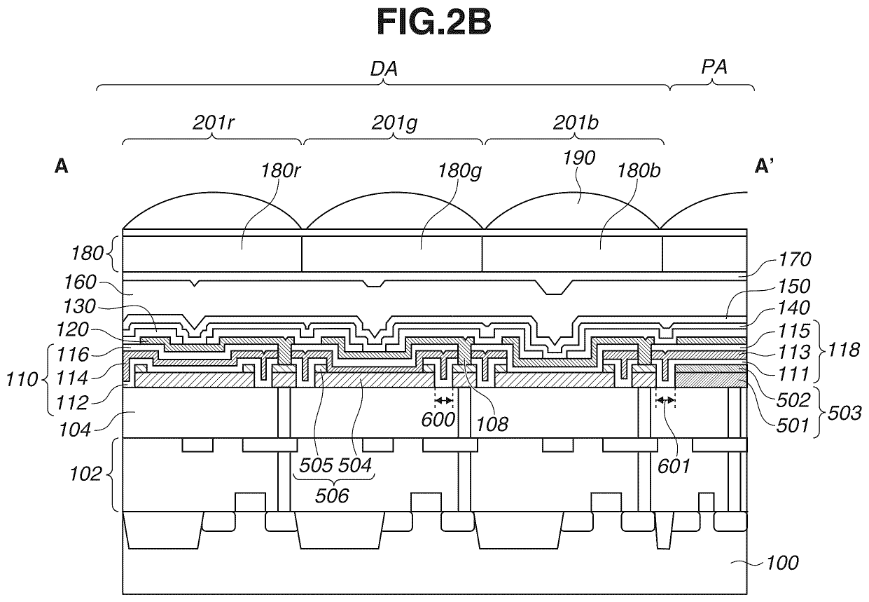

A display apparatus according to a first exemplary embodiment will be described with reference to FIGS. 1A to 2B. FIG. 1A is a plan view of the display apparatus according to the first exemplary embodiment, and FIG. 1B illustrates a modified example of the display apparatus according to the first exemplary embodiment. FIG. 2A is a sectional view of the display apparatus taken along a line A-A′ illustrated in FIGS. 1A and 1B. FIG. 2B is a sectional view illustrating a modified example of the display apparatus according to the first exemplary embodiment.

The display apparatus according to the first exemplary embodiment has, on a substrate, a display region DA and a peripheral region PA disposed in the vicinity of the display region DA. Each pixel 201 disposed in the display region DA includes a light-emitting element. The light-emitting element may be an organic light-emitting element or an inorganic light-emitting element. The following exemplary embodiments illustrate an example where the light-emitting element included in each pixel 201 is an organic light-emitting element. Each pixel 201 disposed in the peripheral region PA may also include a light-emitting element or an organic light-emitting element.

As illustrated in FIG. 1A, the display region DA includes a first pixel 201r and a second pixel 201g. The first pixel 201r and the second pixel 201g may emit light of the same color, or may emit light of different colors. The display region DA may further include a third pixel 201b, and the third pixel 201b may emit light of the same color as the color of light emitted from the first pixel 201r, or may emit light of a color different from the color of light emitted from the first pixel 201r. The third pixel 201b may emit light of the same color as the color of light emitted from the second pixel 201g, or may emit light of a color different from the color of light emitted from the second pixel 201g. If the first pixel 201r, the second pixel 201g, and the third pixel 201b emit light of the same color, for example, white light may be emitted.

If the first pixel 201r, the second pixel 201g, and the third pixel 201b emit light of different colors, the first pixel 201r, the second pixel 201g, and the third pixel 201b may emit red light, green light, and blue light, respectively.

In this specification, the display region DA indicates a region in which the pixels 201 each including a light-emitting element that contributes to light emission are disposed, and the peripheral region PA indicates a region in which the pixels 201 each including a light-emitting element that does not contribute to light emission are provided. Specifically, the peripheral region PA can be regarded as a region superimposed on a peripheral circuit portion in a plan view with respect to the substrate.

While FIG. 1A illustrates a configuration example in which the pixels 201 are arranged in a delta arrangement, the arrangement of the pixels 201 is not limited to this example. The pixels 201 may be arranged in a stripe arrangement, a Bayer arrangement, a square arrangement, or a PenTile arrangement.

In the display apparatus according to the present exemplary embodiment, a metal layer 506 is disposed in the display region DA and a peripheral metal layer 503 is disposed in the peripheral region PA. The metal layer 506 that can reflect light from the light-emitting element included in the display region DA may also be referred to as a reflection layer. In a plan view with respect to a substrate 100, a first region 601 that isolates the metal layer 506 from the peripheral metal layer 503 is disposed between the display region DA and the peripheral region PA. The first region 601 may be disposed over the pixels 201 that are closest to the peripheral region PA among the pixels 201 arranged in the pixel region DA as illustrated in FIG. 1A, or may be disposed along the pixels 201 that are closest to the peripheral region PA among the pixels 201 arranged in the pixel region DA as illustrated in FIG. 1B.

While FIG. 1A illustrates an example where the peripheral metal layer 503 disposed in the peripheral region PA has a rectangular shape, the shape of the peripheral metal layer is not limited to this example. A pixel arrangement similar to that in the display region DA is applicable, or a pixel arrangement different from that in the display region DA is also applicable.

The display apparatus according to the present exemplary embodiment will be described in more detail with reference to FIGS. 2A and 2B. FIG. 2B differs from FIG. 2A in that the metal layer 506 includes a region 600 and the metal layer 506 that is electrically connected to a lower electrode 120 is isolated from the metal layer 506 that is not electrically connected to the lower electrode 120.

In the display region DA, each pixel 201 includes at least the metal layer 506, an insulating layer 110, the lower electrode 120, a light-emitting layer 140, and an upper electrode 150 in this order from the substrate 100 side.

The peripheral region PA includes at least the peripheral metal layer 503 and a peripheral insulating layer 118 in this order from the substrate 100 side.

In the display apparatus according to the present exemplary embodiment, a drive circuit layer 102 and an interlayer insulating layer 104 are disposed over the substrate 100.

The substrate 100 may be a semiconductor substrate, such as a silicon substrate, or a resin substrate. The substrate 100 may include a metal oxide semiconductor (MOS) transistor for driving the light-emitting element and an element isolation region (e.g., shallow trench isolation [STI]). The MOS transistor includes a gate electrode and source and drain regions.

The drive circuit layer 102 is provided with the interlayer insulating layer 104, and a wiring layer is provided in the interlayer insulating layer 104. The interlayer insulating layer 104 may be provided with conductive plugs for connecting the wiring layer and the MOS transistor included in the substrate 100 to each other. Any conductive plugs that can electrically connect the wiring layer to the MOS transistor included in the substrate 100 are useable. Specifically, a conductive material such as tungsten (W) may be used. The conductive plugs may contain a barrier metal such as titanium (Ti), titanium nitride (TiN), or Ti/TiN. The wiring layer may be formed of AlCu and may contain a barrier metal, such as Ti, TiN, or Ti/TiN.

The interlayer insulating layer 104 included in the drive circuit layer 102 may desirably be a silicon oxide, silicon oxynitride, silicon nitride, or boron phosphorus silicate glass (BPSG) film. The interlayer insulating layer 104 may be formed by, for example, a chemical vapor deposition (CVD) method, a thermal CVD method, or a plasma CVD method.

The interlayer insulating layer 104 includes conductive plugs for connecting the drive circuit layer 102 and the metal layer 506 to each other. Specifically, the wiring layer disposed in the drive circuit layer 102 is connected to the metal layer 506. The interlayer insulating layer 104 may be disposed with conductive plugs for connecting the drive circuit layer 102 and the peripheral metal layer 503 to each other. Specifically, the wiring layer disposed in the drive circuit layer 102 is connected to the peripheral metal layer 503. Any conductive plugs that can electrically connect the wiring layer to the metal layer 506 or the wiring layer to the peripheral metal layer 503 are useable. Specifically, the above-described conductive material may be used. The conductive plugs may include the above-described barrier metal.

The interlayer insulating layer 104 may desirably be a silicon oxide, silicon oxynitride, silicon nitride, or BPSG film. The interlayer insulating layer 104 may be formed by, for example, a CVD method, a thermal CVD method, or a plasma CVD method.

The peripheral metal layer 503 includes at least a first metal layer 501. The peripheral metal layer 503 may further include a first layer 502 that is different from the first metal layer 501, as appropriate. The first metal layer 501 is not particularly limited as long as the first metal layer 501 can reflect light, but may desirably have a reflectance of 80% or more. Specifically, metallic materials such as aluminum (Al), silver (Ag), platinum (Pt), nickel (Ni), or Ti, and alloys obtained by adding silicon (Si), copper (Cu), Ni, neodymium (Nd), or Ti to the metallic materials. The first metal layer 501 may desirably be made of Al or an alloy containing Al. This is because the first metal layer 501 can be more finely patterned. The first layer 502 is not particularly limited as long as the first layer 502 can prevent reflection of light. Specifically, Ti, TiN, Ti/TiN, or the like may be used. In other words, the reflectance of the first metal layer 501 may desirably be higher than the reflectance of the first layer 502. The first metal layer 501 may be in contact with the first layer 502. The first metal layer 501 may be closer to the substrate 100 than the first layer 502 is to the substrate 100. The peripheral metal layer 503 may further include the first layer 502 between the first metal layer 501 and the interlayer insulating layer 104.

The metal layer 506 includes at least a second metal layer 504. The metal layer 506 may further include a second layer 505 that is different from the second metal layer 504, as appropriate. The second metal layer 504 is not particularly limited as long as the second metal layer 504 can reflect light, and may preferably have a reflectance of 80% or more. Specifically, the above-described materials may be used. The second metal layer 504 may desirably be made of Al or an alloy containing Al. This is because the second metal layer 504 can be more finely patterned. The second layer 505 is not particularly limited as long as the second layer 505 can prevent reflection of light. Specifically, the above-described materials may be used. In other words, the reflectance of the second metal layer 504 may desirably be higher than the reflectance of the second layer 505. The second metal layer 504 may be in contact with the second layer 505. The second metal layer 504 may be closer to the substrate 100 than the second layer 505 is to the substrate 100.

The metal layer 506 may further include the second layer 505 between the second metal layer 504 and the interlayer insulating layer 104.

If the metal layer 506 includes the second layer 505, the metal layer 506 includes a region where no second layer 505 is disposed so that the second metal layer 504 is exposed. In a plan view with respect to the substrate 100, the region where no second layer 505 is disposed is superimposed on a region where no insulator portion 130 (described below) is disposed.

The peripheral metal layer 503 and the metal layer 506 may desirably be disposed in the same layer. Specifically, the peripheral metal layer 503 and the metal layer 506 may desirably be disposed over the interlayer insulating layer 104. It is further desirable that the peripheral metal layer 503 and the metal layer 506 be disposed in contact with the interlayer insulating layer 104. With this configuration, the peripheral metal layer 503 and the metal layer 506 can be formed at the same time, which is desirable from the viewpoint of processes.

From the viewpoint of processes, the first metal layer 501 and the second metal layer 504 may desirably be made of the same material. If the peripheral metal layer 503 and the metal layer 506 further include the first layer 502 and the second layer 505, the first layer 502 and the second layer 505 may desirably be made of the same material.

The insulating layer 110 is disposed on the metal layer 506 and is made of a material through which light emitted from the light-emitting element can be transmitted. Specific examples of the material include an inorganic material such as silicon nitride, silicon oxynitride, or silicon oxide, and an organic material such as acrylic resin, polyimide resin, epoxy resin, or silicon resin. The insulating layer 110 can be formed by a known method such as a sputtering method or a CVD method. From the viewpoint of ease of processing, silicon oxide may desirably be used.

The peripheral insulating layer 118 is disposed to cover the peripheral metal layer 503, and is made of a material similar to the material used for the insulating layer 110. The peripheral insulating layer 118 includes a first peripheral insulating layer 111, and may further include, as appropriate, a second peripheral insulating layer 113 and/or a third peripheral insulating layer 115.

In the insulating layer 110 of each pixel 201 included in the display region DA, the film thickness of the insulating layer 110 may vary among the plurality of pixels 201 depending on the emission wavelength of light emitted from the light-emitting element. In other words, the light-emitting element may have an optical resonator structure. In this case, the light-emitting element may be an organic light-emitting element. Specifically, the insulating layer 110 included in the first pixel 201r and the insulating layer 110 included in the second pixel 201g may have different film thicknesses. If the plurality of pixels 201 further includes the third pixel 201b, the insulating layer 110 included in the first pixel 201r, the insulating layer 110 included in the second pixel 201g, and the insulating layer 110 included in the third pixel 201b may have different film thicknesses. More specifically, the pixel (e.g., red light-emitting pixel) 201r with the longest emission wavelength may include a first insulating layer 112, a second insulating layer 114, and a third insulating layer 116. The pixel (e.g., blue light-emitting pixel) 201b with the shortest emission wavelength may include only the first insulating layer 112. The pixel (e.g., green light-emitting pixel) 201g with an emission wavelength that is shorter than that of the pixel 201r and is longer than that of the pixel 201b may include the first insulating layer 112 and the second insulating layer 114. The insulating layer 110 may include a void between the plurality of pixels 201 or in the first region 601.

The lower electrode 120 is not particularly limited as long as the lower electrode 120 can transmit light emitted from light-emitting element toward the substrate 100. The lower electrode 120 may desirably be made of a transparent material. Specifically, a thin film made of a conductive material such as a conducting oxide such as indium tin oxide (ITO) or indium zinc oxide (IZO), a metal such as Al, Ag, or Pt, or an alloy thereof, or a metal oxide may be used. In the display apparatus according to the present exemplary embodiment, the lower electrode 120 is also disposed at an opening 108 that is formed in the insulating layer 110. The lower electrode 120 and the metal layer 506 are electrically connected. The film thickness of the lower electrode 120 is not particularly limited. The lower electrode 120 may have a uniform film thickness or an uneven film thickness. Specifically, the film thickness of the lower electrode 120 may be in a range from 20 nm to 100 nm inclusive.

The lower electrode 120 may further include the insulator portion 130 that is disposed to cover an end of the lower electrode 120. The insulator portion 130 is also referred to as a bank and is disposed to electrically insulate the lower electrode 120 among the plurality of pixels 201. The insulator portion 130 may be formed of an inorganic material such as silicon nitride, silicon oxynitride, or silicon oxide, or an organic material such as acrylic resin, polyimide resin, epoxy resin, or silicon resin. The insulator portion 130 can be formed by a known method such as a sputtering method or a CVD method.

The light-emitting layer 140 is a layer that emits light. The light-emitting layer 140 may include not only the layer that emits light, but also a carrier-transport layer and a carrier-blocking layer. The light-emitting layer 140 may continuously be arranged among the plurality of pixels 201, or may be arranged independently of each pixel 201. If the light-emitting layer 140 is continuously arranged among the plurality of pixels 201, each pixel 201 may include a color filter to be described below. If the light-emitting layer 140 is disposed independently of each pixel 201, each pixel 201 may exclude a color filter to be described below.

The upper electrode 150 is made of a material through which light emitted from the light-emitting layer 140 can be transmitted.

Specifically, a semi-transmissive and reflective material formed of a thin film made of a transparent conducting oxide material such as ITO or IZO, a metal such as Al, Ag, or Au, an alkali metal such as lithium (Li) or cesium (Cs), an alkali earth metal such as Mg, calcium (Ca), or beryllium (Ba), or an alloy containing these metals. In particular, the upper electrode 150 may desirably be made of Ag or an alloy of Mg and Ag. The upper electrode 150 may be formed of a single layer or a plurality of layers, as long as the upper electrode 150 can transmit light.

The display apparatus according to the present disclosure may further include a sealing layer 160, a planarization layer 170, a color filter layer 180, and an optical member 190 over the upper electrode 150.

The sealing layer 160 is disposed on the upper electrode 150 and has a role of protecting the organic light-emitting element against immersion of air and water. A material forming the sealing layer 160 is not particularly limited. However, a material that has light-transmitting properties and is capable of preventing immersion of oxygen and water from the outside may desirably be used. Specifically, an inorganic material such as silicon nitride, silicon oxynitride, silicon oxide, aluminum oxide, or titanium oxide, or an organic material such as acrylic resin, polyimide resin, epoxy resin, or silicon resin may be used.

The sealing layer 160 can be formed by a known method such as a CVD method, an atomic layer deposition method (ALD method), or a sputtering method.

The sealing layer 160 may be formed of a single layer or a plurality of layers, as long as the sealing layer 160 has the above-described functions. In particular, if the sealing layer 160 is formed of a plurality of layers, the sealing layer 160 may have a stacked structure that is made only of an inorganic material or made only of an organic material, or may have a stacked structure including both an inorganic material and an organic material. The sealing layer 160 may be formed over the plurality of pixels 201.

The planarization layer 170 may be formed on the sealing layer 160. The planarization layer 170 is disposed to reduce the unevenness of the lower layer. A material forming the planarization layer 170 is not particularly limited. The planarization layer 170 may be formed of an inorganic material or an organic material. If the planarization layer 170 is formed of an organic material, the planarization layer 170 may be formed of a low-molecular material or a high-molecular material.

The planarization layer 170 may desirably be formed by a wet process such as a spin coating method, a dip coating method, a slit coating method, or a blade coating method. The formation of the planarization layer 170 through the wet process facilitates planarization of the light-emitting-side surface of the planarization layer 170. The planarization layer 170 formed through the wet process may desirably be cured by heating, ultraviolet (UV) irradiation, or the like after the formation. The planarization layer 170 may be formed over a plurality of organic light-emitting elements.

The color filter layer 180 may desirably be formed on the planarization layer 170 (the side opposite to the one facing the substrate 100). Light transmitted through a color filter layer 180r included in the first pixel 201r, light transmitted through a color filtering layer 180g included in the second pixel 201g, and light transmitted through a color filter layer 180b included in the third pixel 201b may have the same wavelength or different wavelengths.

The color filter layer 180 may be formed by applying a color resist on a foundation layer such as the planarization layer 170 and then patterning the coated layer using lithography. The color resist is formed of, for example, photo-curable resin. A pattern is formed by curing a portion irradiated with UV light.

The optical member 190 may be disposed on a color filter layer 180 (the side opposite to the one facing the substrate 100) or below the color filter layer 180 (the side facing the substrate 100). The optical member 190 may be a lens, and the shape of the optical member 190 is not particularly limited. The optical member 190 may be convex toward the light-emitting layer 140, or may be convex in a direction opposite to the light-emitting layer 140. If the optical member 190 is a lens, the optical member 190 may also be referred to as a microlens. The microlens may be a spherical microlens, an aspherical microlens, or an asymmetrical microlens.

The optical member 190 is formed of a material with light-transmitting properties. Specifically, the optical member 190 is formed of, for example, an organic material such as acrylic resin, epoxy resin, or silicon resin, or an inorganic material such as silicon nitride, silicon oxynitride, or silicon oxide.

In a case where the optical member 190 is convex in the direction opposite to the light-emitting layer 140, the light exit side of the optical member 190 is disposed with a material with a lower refractive index than that of the material forming the optical member 190. In particular, a material with a lower refractive index, for example, a gas such as air or nitrogen, or silica aerogel, may desirably be used, or a vacuum state may be desirable. When the optical member 190 is convex toward the light-emitting layer 140, the light exit side is disposed with a material with a higher refractive index than that of the material forming the lens.

The display apparatus according to the present disclosure will be described in detail below.

In the display apparatus discussed in Japanese Patent Application Laid-Open No. 2021-72282 (PTL 1) as a comparative example, with a large width of the first region 601 disposed between the display region DA and the peripheral region PA, the insulating layer 110 cannot be easily deposited in some regions between the display region DA and the peripheral region PA. As a result, the upper electrode 150 disposed in such regions is prone to thinning or breakage. Accordingly, in the display apparatus discussed in PTL 1, the resistance of the upper electrode 150 can increase.

In contrast to this, in the display apparatus according to the present disclosure, the width of the first region 601 is less than or equal to twice the film thickness of the insulating layer 110 or the peripheral insulating layer 118. Specifically, the width of the first region 601 is less than or equal to twice the film thickness of a thickest portion of the insulating layer 110, or less than or equal to twice the film thickness of a thickest portion of the peripheral insulating layer 118 among the plurality of pixels 201. By satisfying this condition, the film thickness of the upper electrode 150 in the area between the display region DA and the peripheral region PA can be reduced. Consequently, the display apparatus according to the present disclosure can reduce an increase in the resistance of the upper electrode 150.

The width of the first region 601 may be less than or equal to twice the film thickness of the peripheral insulating layer 118 in a cross-section passing through the substrate 100, the display region DA, and the peripheral region PA. More preferably, the width of the first region 601 may be smaller than the film thickness of the peripheral insulating layer 118.

If the metal layer 506 includes the region 600 as illustrated in FIG. 2B, the width of the region 600 may be less than or equal to twice the film thickness of the insulating layer 110 or the peripheral insulating layer 118, or may be less than or equal to twice the film thickness of the insulating layer 110 in a cross-section passing through the substrate 100, the display region DA, and the peripheral region PA. More specifically, the width of the region 600 may be less than or equal to twice the film thickness of a thickest portion of the insulating layer 110 among the plurality of pixels 201.

While FIGS. 1A and 1B illustrate only a part of the peripheral metal layer 503, this also applies to the other outer peripheral portions. Specifically, the first region 601 may be disposed to surround the display region DA and may isolate the metal layer 506 from the peripheral metal layer 503 in a plan view with respect to the substrate 100.

In this specification, the term “width” refers to a length in a direction parallel to the substrate 100 in a cross-section passing through the substrate 100, the display region DA, and the peripheral region PA. The term “film thickness” refers to a length in a direction perpendicular to the substrate 100 in a cross-section passing through the substrate 100, the display region DA, and the peripheral region PA.

The display apparatus according to the present exemplary embodiment can be obtained through a known process, except that when the metal layer 506 and the peripheral metal layer 503 are patterned, the width of the first region 601 is controlled to be less than or equal to twice the film thickness of the insulating layer 110.

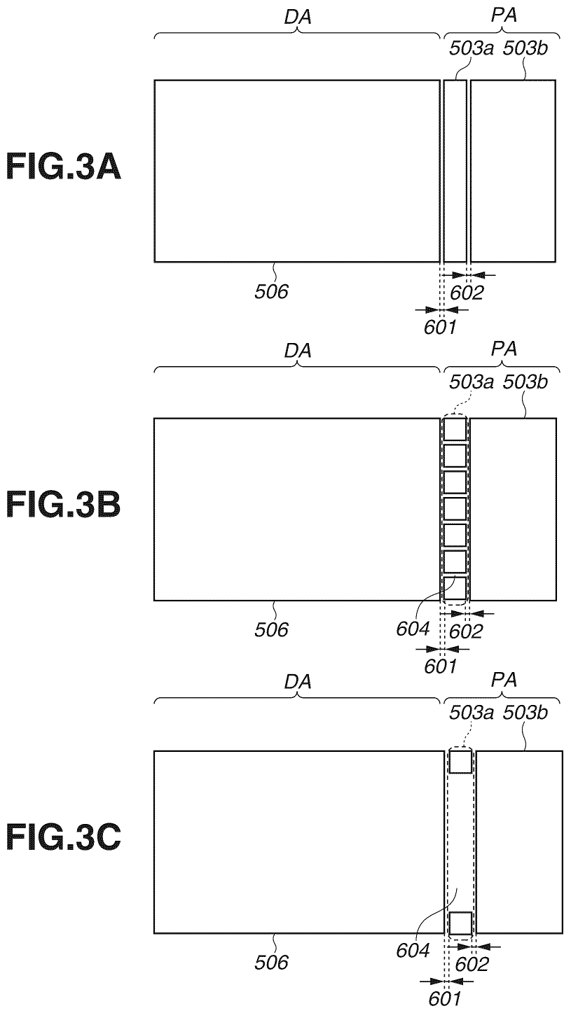

A display apparatus according to a second exemplary embodiment will be described with reference to FIGS. 3A to 3C. FIGS. 3A to 3C are plan views each illustrating the display apparatus according to the second exemplary embodiment. To simplify the illustration, the metal layer 506 and the peripheral metal layer 503 are each represented by a rectangular shape. However, the shape of each of the metal layer 506 and the peripheral metal layer 503 is not limited to a rectangular shape. The display apparatus according to the second exemplary embodiment differs from the display apparatus according to the first exemplary embodiment in the following aspects.

In the display apparatus according to the second exemplary embodiment, the peripheral metal layer 503 includes a first peripheral metal layer 503a and a second peripheral metal layer 503b in the peripheral region PA. In a plan view with respect to the substrate 100, the first peripheral metal layer 503a is disposed between the metal layer 506 and the second peripheral metal layer 503b. The first region 601 is disposed between the metal layer 506 and the first peripheral metal layer 503a, and a second region 602 is disposed between the first peripheral metal layer 503a and the second peripheral metal layer 503b. With this configuration, the display apparatus according to the second exemplary embodiment can further reduce an undesirable electrical connection between the metal layer 506 and the peripheral metal layer 503 due to a defective pattern caused by a foreign substance or defocusing.

The second region 602 illustrated in FIG. 3A is disposed in parallel to the first region 601. However, the second region 602 may be disposed in such a manner that the first peripheral metal layer 503a and the second peripheral metal layer 503b can be isolated from each other. The same potential or different potentials may be applied to the first peripheral metal layer 503a and the second peripheral metal layer 503b.

The width of the second region 602 is not particularly limited. The width of the second region 602 may be less than or equal to twice the film thickness of the insulating layer 110 and may be less than or equal to twice the film thickness of the peripheral insulating layer 118 in a cross-section passing through the substrate 100, the display region DA, and the peripheral region PA. Specifically, the width of the second region 602 may be less than or equal to twice the film thickness of a thickest portion of the insulating layer 110 or may be less than or equal to twice the film thickness of a thickest portion of the peripheral insulating layer 118 among the plurality of pixels 201. In this case, the peripheral insulating layer 118 may be an insulating layer disposed on the first peripheral metal layer 503a, or may be an insulating layer disposed on the second peripheral metal layer 503b.

As illustrated in FIGS. 3B and 3C, the first peripheral metal layer 503a may further include a fourth region 604 that connects the first region 601 and the second region 602 to each other. With this configuration, an undesirable electrical connection between the metal layer 506 and the peripheral metal layer 503 can be further reduced.

In the present exemplary embodiment, the fourth region 604 is disposed in the first peripheral metal layer 503a, but instead may be disposed in the second peripheral metal layer 503b. In this case, a region of the fourth region 604 that connects the second region 602 and the outer edge of the second peripheral metal layer 503b to each other may be disposed in the second peripheral metal layer 503b.

The width of the fourth region 604 is not particularly limited. The width of the fourth region 604 may be less than or equal to twice the film thickness of the insulating layer 110 and may be less than or equal to twice the film thickness of the peripheral insulating layer 118 in a cross-section passing through the substrate 100, the display region DA, and the peripheral region PA. Specifically, the width of the fourth region 604 may be less than or equal to twice the film thickness of a thickest portion of the insulating layer 110, or may be less than or equal to twice the film thickness of a thickest portion of the peripheral insulating layer 118 among the plurality of pixels 201. In this case, the peripheral insulating layer 118 may be an insulating layer disposed on the first peripheral metal layer 503a, or may be an insulating layer disposed on the second peripheral metal layer 503b.

In a plan view with respect to the substrate 100, the width of the fourth region 604 may be greater than the width of the first region 601 and may be greater than the width of the second region 602 as illustrated in FIG. 3C. Specifically, the width of the fourth region 604 may be more than twice the film thickness of the insulating layer 110 and may be more than twice the film thickness of the peripheral insulating layer 118 in a cross-section passing through the substrate 100, the display region DA, and the peripheral region PA. More specifically, the width of the fourth region 604 may be more than twice the film thickness of a thickest portion of the insulating layer 110 and may be more than twice the film thickness of a thickest portion of the peripheral insulating layer 118 among the plurality of pixels 201.

The first peripheral metal layer 503a may include a plurality of fourth regions 604 as illustrated in FIG. 3B, or may include a single fourth region 604 as illustrated in FIG. 3C. As in the first exemplary embodiment, the first region 601 and the second region 602 may be disposed to surround the display region DA in a plan view with respect to the substrate 100.

### Third Exemplary Embodiment

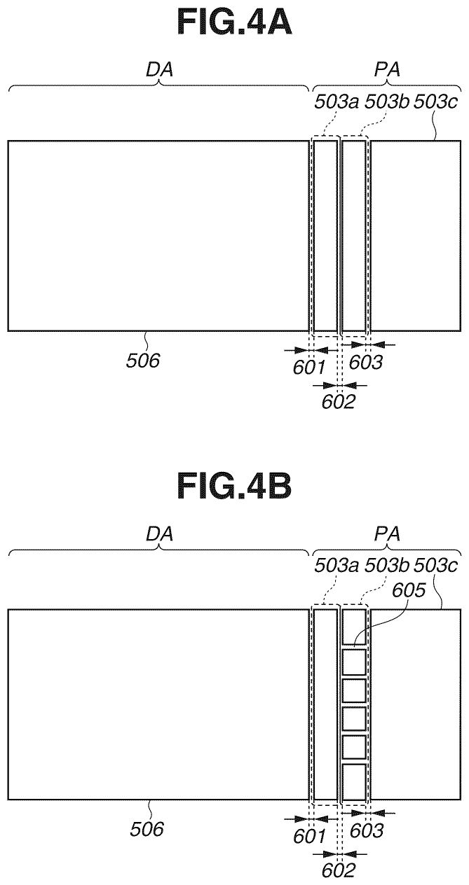

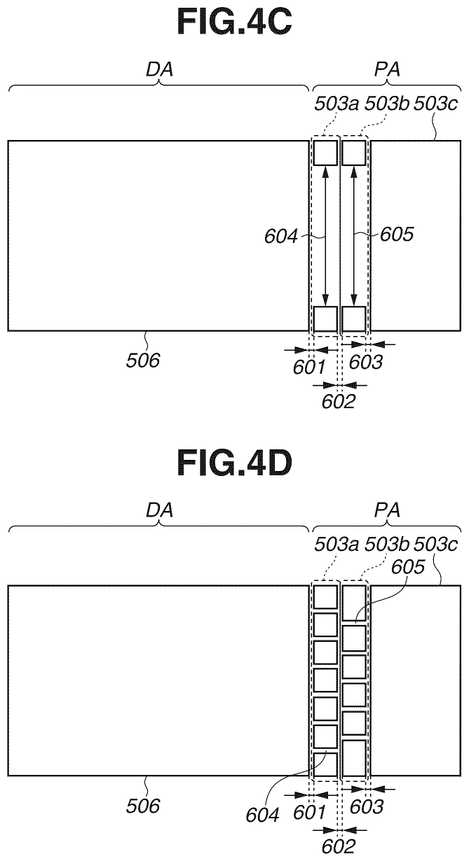

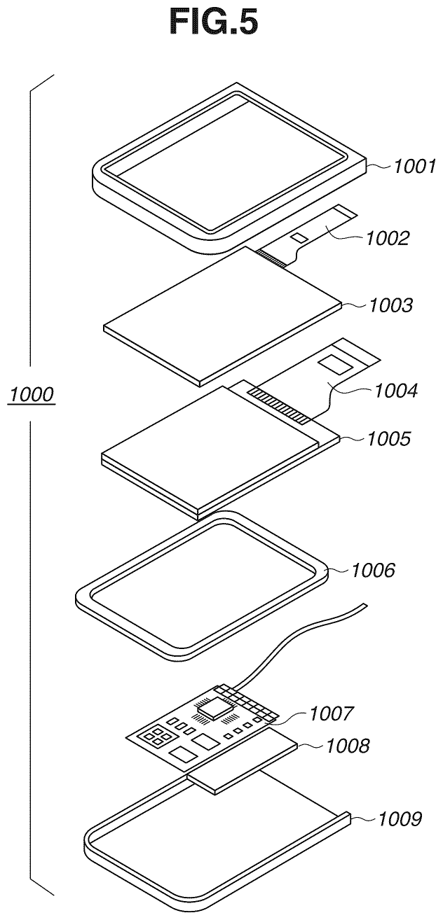

A display apparatus according to a third exemplary embodiment will be described with reference to FIGS. 4A to 4D. FIGS. 4A to 4D are plan views each illustrating the display apparatus according to the third exemplary embodiment. The display apparatus according to the third exemplary embodiment differs from the display apparatus according to the first exemplary embodiment in the following aspects.

In the display apparatus according to the third exemplary embodiment, the peripheral metal layer 503 includes the first peripheral metal layer 503a, the second peripheral metal layer 503b, and a third peripheral metal layer 503c in the peripheral region PA.

In a plan view with respect to the substrate 100, the first peripheral metal layer 503a is disposed between the metal layer 506 and the second peripheral metal layer 503b, and the second peripheral metal layer 503b is disposed between the first peripheral metal layer 503a and the third peripheral metal layer 503c. In a plan view with respect to the substrate 100, the second region 602 that isolates the first peripheral metal layer 503a from the second peripheral metal layer 503b is disposed between the first peripheral metal layer 503a and the second peripheral metal layer 503b. In a plan view with respect to the substrate 100, a third region 603 that isolates the second peripheral metal layer 503b from the third peripheral metal layer 503c is disposed between the second peripheral metal layer 503b and the third peripheral metal layer 503c. With this configuration, the display apparatus according to the third exemplary embodiment can further reduce an undesirable electrical connection between the metal layer 506 and the peripheral metal layer 503 due to a defective pattern caused by a foreign substance or defocusing.

The second region 602 illustrated in FIG. 4A is disposed in parallel to the first region 601. However, the second region 602 may be disposed in such a manner that the first peripheral metal layer 503a and the second peripheral metal layer 503b can be isolated from each other. Similarly, the third region 603 may be disposed in such a manner that the second peripheral metal layer 503b and the third peripheral metal layer 503c can be isolated from each other. The same potential or different potentials may be applied to the first peripheral metal layer 503a, the second peripheral metal layer 503b, and the third peripheral metal layer 503c.

The width of the second region 602 is not particularly limited. The width of the second region 602 may be less than or equal to twice the film thickness of the insulating layer 110 and may be less than or equal to twice the film thickness of the peripheral insulating layer 118 in a cross-section passing through the substrate 100, the display region DA, and the peripheral region PA. Specifically, the width of the second region 602 may be less than or equal to twice the film thickness of a thickest portion of the insulating layer 110, or may be less than or equal to twice the film thickness of a thickest portion of the peripheral insulating layer 118 among the plurality of pixels 201. In this case, the peripheral insulating layer 118 may be an insulating layer disposed on the first peripheral metal layer 503a, may be an insulating layer disposed on the second peripheral metal layer 503b, or may be an insulating layer disposed on the third peripheral metal layer 503c. The width of the third region 603 is not particularly limited as well. The width of the third region 603 may be less than or equal to twice the film thickness of the insulating layer 110 and may be less than or equal to twice the film thickness of the peripheral insulating layer 118 in a cross-section passing through the substrate 100, the display region DA, and the peripheral region PA. Specifically, the width of the third region 603 may be less than or equal to twice the film thickness of a thickest portion of the insulating layer 110, or may be less than or equal to twice the film thickness of a thickest portion of the peripheral insulating layer 118 among the plurality of pixels 201. In this case, the peripheral insulating layer 118 may be an insulating layer disposed on the first peripheral metal layer 503a, may be an insulating layer disposed on the second peripheral metal layer 503b, or may be an insulating layer disposed on the third peripheral metal layer 503c.

As illustrated in FIGS. 4B and 4C, the second peripheral metal layer 503b may include a fifth region 605 that connects the second region 602 and the third region 603 to each other. While FIG. 4B illustrates an example where the second peripheral metal layer 503b includes the fifth region 605 and the first peripheral metal layer 503a does not include the fourth region 604, the configuration according to the present exemplary embodiment is not limited to this example. The first peripheral metal layer 503a may include the fourth region 604 that connects the first region 601 and the second region 602 to each other and the second peripheral metal layer 503b may exclude the fifth region 605. The first peripheral metal layer 503a may include the fourth region 604 and the second peripheral metal layer 503b may include the fifth region 605.

With the configurations described above, an undesirable electrical connection between the metal layer 506 and the peripheral metal layer 503 can be further reduced.

In the present exemplary embodiment, the fifth region 605 is disposed in the second peripheral metal layer 503b. In addition, a region that connects the third region 603 to the outer edge of the third peripheral metal layer 503c may be disposed in the third peripheral metal layer 503c.

The width of the fifth region 605 is not particularly limited. The width of the fifth region 605 may be less than or equal to twice the film thickness of the insulating layer 110 and may be less than or equal to twice the film thickness of the peripheral insulating layer 118 in a cross-section passing through the substrate 100, the display region DA, and the peripheral region PA. Specifically, the width of the fifth region 605 may be less than or equal to twice the film thickness of a thickest portion of the insulating layer 110, or may be less than or equal to twice the film thickness of a thickest portion of the peripheral insulating layer 118 among the plurality of pixels 201. In this case, the peripheral insulating layer 118 may be an insulating layer disposed on the first peripheral metal layer 503a, may be an insulating layer disposed on the second peripheral metal layer 503b, or may be an insulating layer disposed on the third peripheral metal layer 503c. As illustrated in FIG. 4C, the width of the fifth region 605 may be greater than the width of the first region 601, may be greater than the width of the second region 602, and may be greater than the width of the third region 603 in a plan view with respect to the substrate 100. Specifically, the width of the fifth region 605 may be more than twice the film thickness of the insulating layer 110 and may be more than twice the film thickness of the peripheral insulating layer 118 in a cross-section passing through the substrate 100, the display region DA, and the peripheral region PA. More specifically, the width of the fifth region 605 may be more than twice the film thickness of a thickest portion of the insulating layer 110 and may be more than twice the film thickness of a thickest portion of the peripheral insulating layer 118 among the plurality of pixels 201.

The second peripheral metal layer 503b may include a plurality of fifth regions 605 as illustrated in FIG. 4B, or may include a single fifth region 605 as illustrated in FIG. 4C. As in the first exemplary embodiment, the first region 601, the second region 602, and the third region 603 may be disposed to surround the display region DA.

When the first peripheral metal layer 503a includes the fourth region 604 and the second peripheral metal layer 503b includes the fifth region 605, it is desirable that an intersection between the second region 602 and the fourth region 604 do not match an intersection between the second region 602 and the fifth region 605 in a plan view with respect to the substrate 100. This is because the region where the insulating layer 110 is not easily deposited can be reduced by providing the fourth region 604 and the fifth region 605 in such a manner that the intersection between the second region 602 and the fourth region 604 does not match the intersection between the second region 602 and the fifth region 605. As a result, the upper electrode 150 is less prone to thinning or breakage, which makes it possible to further reduce an increase in the resistance of the upper electrode 150. Specifically, a configuration illustrated in FIG. 4D may desirably be used. An arrangement illustrated in FIG. 4D can be paraphrased as a state where the regions are arranged in a lattice, a state where the regions are arranged in a staggered manner, or a checkered pattern.

With this configuration, the display apparatus according to the present exemplary embodiment can further reduce an undesirable electrical connection between the metal layer 506 and the peripheral metal layer 503 due to a defective pattern caused by a foreign substance or defocusing. Thinning or step disconnection of the upper electrode 150 in the first region 601 can be reduced, so that an increase in the resistance of the upper electrode 150 can be further reduced. (Application Examples)

FIG. 5 is a schematic view illustrating an example of the display apparatus according to any one of the foregoing exemplary embodiments. A display apparatus 1000 may include a touch panel 1003, a display panel 1005, a frame 1006, a circuit board 1007, and a battery 1008, which are disposed between an upper cover 1001 and a lower cover 1009. The touch panel 1003 and the display panel 1005 are connected to flexible printed circuits (FPCs) 1002 and 1004, respectively. The display panel 1005 may include the display apparatus according to any one of the foregoing exemplary embodiments. A transistor is printed on the circuit board 1007. If the display apparatus is not a mobile device, the battery 1008 can be omitted. Even in a case where the display apparatus is a mobile device, the battery 1008 may be disposed at another location.

The display apparatus according to any one of the foregoing exemplary embodiments may include red, green, and blue color filters. The red, green, and blue color filters may be arranged in a delta arrangement.

The display apparatus according to the present exemplary embodiment may be used for a display unit of an image capturing apparatus including an image sensor that receives light. The image capturing apparatus may include a display unit that displays information obtained by the image sensor. The display unit may be a display unit that is exposed to the outside of the image capturing apparatus, or may be a display unit disposed within a viewfinder. The image capturing apparatus may be a digital camera or a digital video camera.

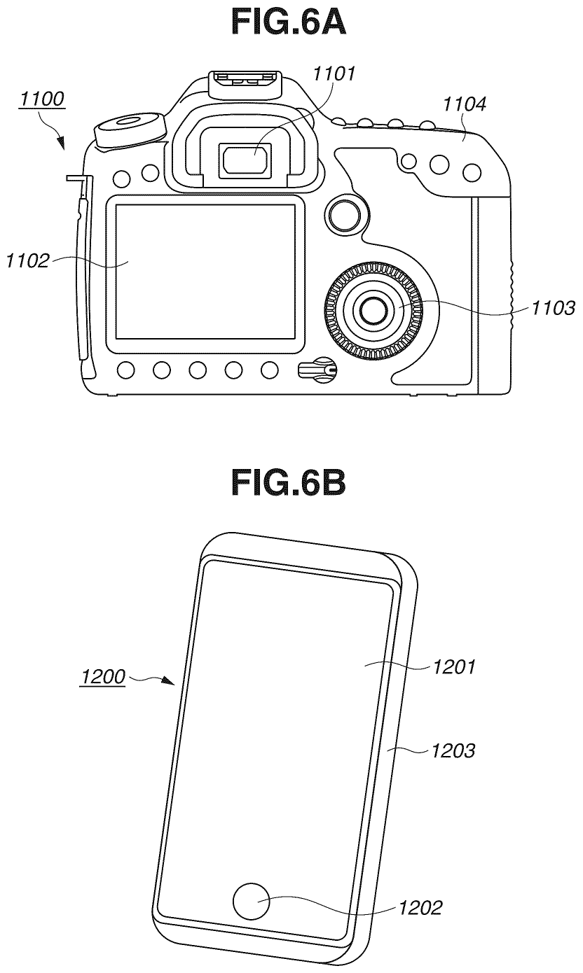

FIG. 6A is a schematic view illustrating an example of an image capturing apparatus according to the present exemplary embodiment. An image capturing apparatus 1100 may include a viewfinder 1101, a rear display 1102, an operation unit 1103, and a housing 1104. The viewfinder 1101 and the rear display 1102 may include the display apparatus according to any one of the foregoing exemplary embodiments. In this case, the display apparatus may display not only captured images, but also environmental information, an image capturing instruction, and other types of information. The environmental information may include the intensity of outside light, the orientation of outside light, the moving speed of an object, and the possibility of an object being obscured by obstacles.

The image capturing apparatus 1100 may further include an optical portion (not illustrated). One or more lenses may be included in the optical portion and may focus an image on an image sensor accommodated in the housing 1104. A plurality of lenses may adjust relative positions thereof, thus adjusting a focal point. This operation can also be automatically performed. The image capturing apparatus may also be referred to as a photoelectric conversion apparatus. The photoelectric conversion apparatus may include, as an image capturing method, not only a sequential image capturing method, but also a method of detecting differences from a previous image, a method of clipping an image from a constantly recorded image, or other methods.

FIG. 6B is a schematic view illustrating an example of an electronic apparatus according to any one of the foregoing exemplary embodiments. An electronic apparatus 1200 includes a display unit 1201, an operation unit 1202, and a housing 1203. The display unit 1201 may include the display apparatus according to any one of the foregoing exemplary embodiments. The housing 1203 may include a circuit, a printed board including the circuit, a battery, and a communication unit. The operation unit 1202 may be a button or a reaction portion of a touch panel type. The operation unit 1202 may be a biometric recognition unit configured to recognize a fingerprint for unlocking, for example. Such an electronic apparatus including a communication unit can also be referred to as a communication apparatus. The electronic apparatus may further include a lens and an image sensor, thus providing a camera function. Images captured by the camera function are displayed on the display unit 1201. Examples of the electronic apparatus include smartphones and notebook computers.

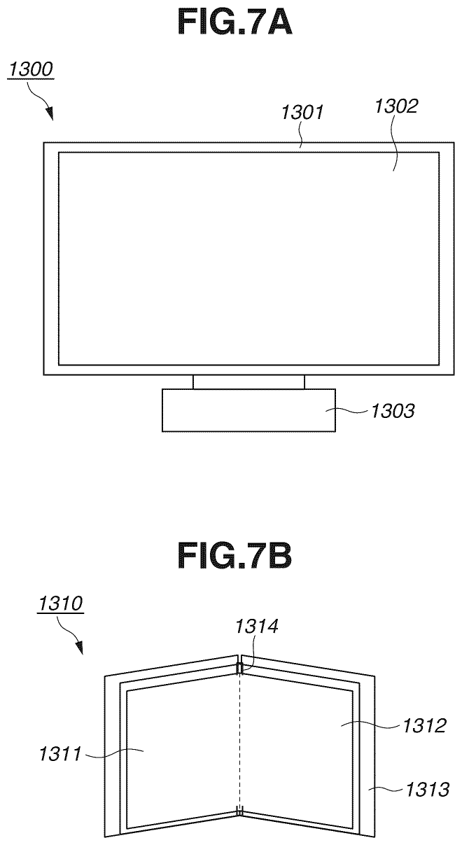

FIGS. 7A and 7B are schematic views each illustrating an example of the display apparatus according to any one of the foregoing exemplary embodiments. FIG. 7A illustrates a display apparatus such as a television monitor or a personal computer (PC) monitor. A display apparatus 1300 includes a housing 1301 and a display unit 1302. The display apparatus according to any one of the foregoing exemplary embodiments. may be used as the display unit 1302.

The display apparatus 1300 may further include a base 1303 that supports the housing 1301 and the display unit 1302. The form of the base 1303 is not limited to the one illustrated in FIG. 11A. The lower side of the housing 1301 may also function as the base.

The housing 1301 and the display unit 1302 may be curved. The radius of the curvature may be in a range from 5000 mm to 6000 mm inclusive.

FIG. 7B is a schematic view illustrating another example of the display apparatus according to the present exemplary embodiment. A display apparatus 1310 illustrated in FIG. 7B can be folded, in other words, the display apparatus 1310 is a foldable display apparatus. The display apparatus 1310 includes a first display unit 1311, a second display unit 1312, a housing 1313, and a folding point 1314. The first display unit 1311 and the second display unit 1312 may include the display apparatus according to the any one of the foregoing exemplary embodiments. The first display unit 1311 and the second display unit 1312 may be integrally formed as a single seamless display apparatus. The first display unit 1311 and the second display unit 1312 can be sectioned with respect to the folding point 1314. The first display unit 1311 and the second display unit 1312 may display different images, or the first display unit 1311 and the second display unit 1312 may display a single image.

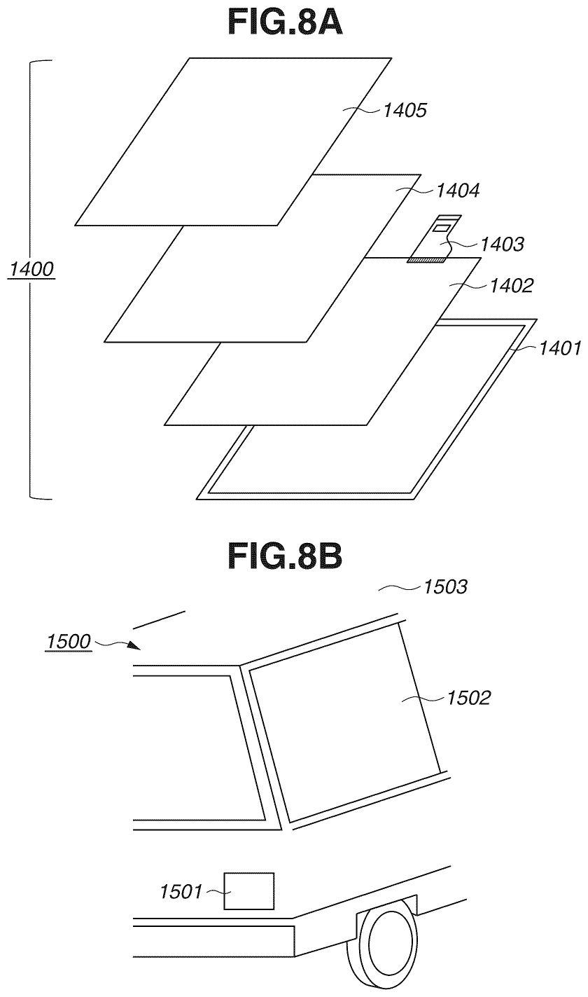

FIG. 8A is a schematic view illustrating an example of an illumination apparatus according to any one of the foregoing exemplary embodiments. An illumination apparatus 1400 may include a housing 1401, a light source 1402, and a circuit board 1403. The light source 1402 may include the display apparatus according to any one of the foregoing exemplary embodiments. The illumination apparatus 1400 may include an optical film 1404 to improve color rendering properties of the light source 1402. The illumination apparatus 1400 may include a light diffusion unit 1405 to effectively diffuse light from the light source 1402. The illumination apparatus 1400 including the light diffusion unit 1405 can deliver the light to a wide area. The optical film 1404 and the light diffusion unit 1405 may be disposed on the light exit side of the illumination. The illumination apparatus 1400 may include a cover on an outermost portion thereof, as appropriate.

The illumination apparatus 1400 is, for example, an indoor illumination apparatus. The color of light to be emitted from the illumination apparatus 1400 may be white, daylight white, or any color in the range from blue to red. The illumination apparatus 1400 may include a light modulation circuit for modulating the light to be emitted. The illumination apparatus 1400 may include a power supply circuit. The power supply circuit may be a circuit for converting an alternating current voltage into a direct current voltage. In this case, “white” is a color with a color temperature of 4200 K (Kelvin), and “daylight white” is a color with a color temperature of 5000 K. The illumination apparatus 1400 may include a color filter.

The illumination apparatus 1400 according to the present exemplary embodiment may include a heat dissipation unit. The heat dissipation unit dissipates heat in the apparatus to the outside of the apparatus, and is made of, for example, a metal or ceramic having a high thermal conductivity.

FIG. 8B is a schematic view illustrating an automobile as an example of a movable body according to the present exemplary embodiment. The automobile includes a taillight as an example of a lighting tool. An automobile 1500 includes a taillight 1501. The taillight 1501 may be configured to turn on when a brake operation is applied. The automobile 1500 may include a vehicle body 1503 and a window 1502 attached to the vehicle body 1503.

The taillight 1501 may include the display apparatus according to any one of the foregoing exemplary embodiments. The taillight 1501 may include a protective member that protects a light source. The protective member may be made of any material that has a relatively high strength and is transparent. It is however desirable that the protective member be made of, for example, polycarbonate. The polycarbonate may be mixed with, for example, a furandicarboxylic acid derivative or an acrylonitrile derivative.

The movable body according to the present exemplary embodiment includes one or both of a driving force generation unit that generates a driving force mainly used to move the movable body, and a rotary member mainly used to move the movable body. The driving force generation unit may be an engine, a motor, or the like. The rotary member may be a tire, a wheel, a screw of a ship, a propeller of a flight vehicle, or the like. Specific examples of the movable body may include a bicycle, an automobile, a train, a ship, an aircraft, and a drone. The movable body may include a body and a lighting tool disposed on the body. The lighting tool may emit light to show the position of the body.

The electronic apparatus or the display apparatus can be applied to, for example, a system attachable to a user as a wearable device, such as smartglasses, a head-mounted display, or smart contact lenses. The electronic apparatus may include an image capturing apparatus configured to perform photoelectric conversion on visible light and a display apparatus configured to emit visible light.

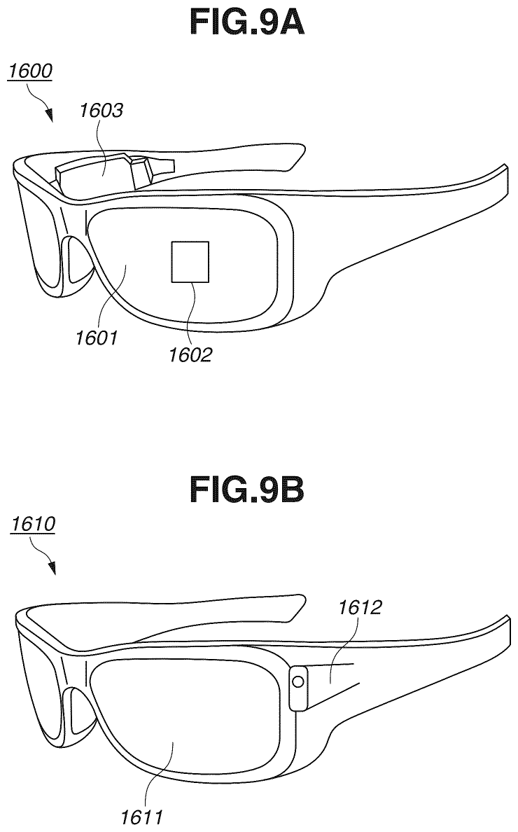

FIGS. 9A and 9B are schematic views each illustrating an example of eyeglasses (smartglasses) according to the present exemplary embodiment. Eyeglasses 1600 (smartglasses) will be described with reference to FIG. 9A. The eyeglasses 1600 include a display unit on the back side of a lens 1601. The display unit may include the display apparatus according to any one of the foregoing exemplary embodiments. Further, the front surface of the lens 1601 may be provided with an image capturing apparatus 1602 such as a complementary metal-oxide semiconductor (CMOS) sensor or a single photon avalanche diode (SPAD) sensor.

The eyeglasses 1600 further include a control device 1603. The control device 1603 functions as a power supply to supply electric power to each of the image capturing apparatus 1602 and the display unit. The control device 1603 controls operations of the image capturing apparatus 1602 and the display unit. The lens 1601 includes an optical system for collecting light of the image capturing apparatus 1602 and the display unit.

Eyeglasses 1610 (smartglasses) will be described with reference to FIG. 9B. The eyeglasses 1610 include a control device 1612. The control device 1612 is disposed with a display apparatus including the display apparatus according to any one of the foregoing exemplary embodiments. The control device 1612 may further include an image capturing apparatus corresponding to the image capturing apparatus 1602. A lens 1611 includes an optical system for projecting light emitted from the control device 1612, and an image is projected onto the lens 1611. The control device 1612 functions as a power supply to supply electric power to each of the image capturing apparatus and the display apparatus, and controls operations of the image capturing apparatus and the display apparatus. The control device 1612 may include a line-of-sight detection unit that detects the line of sight of a wearer. Infrared light may be used to detect the line of sight. An infrared-light-emitting unit emits infrared light toward an eyeball of the user gazing at a displayed image. A portion of the emitted infrared light that is reflected by the eyeball is detected by an image capturing unit including a light-receiving element. Thus, a captured image of the eyeball can be obtained. A light reducing unit that reduces light traveling from the infrared-light-emitting unit to the display unit in a plan view may be further disposed to reduce degradation of the image quality.

The control device 1612 detects the line of sight of the user viewing the displayed image based on the captured eyeball image obtained by image capturing using infrared light. Any known methods may be used to detect the line of sight based on the captured eyeball image. For example, a line-of-sight detection method based on a Purkinje image obtained by reflection of irradiation light by a cornea can be used.

More specifically, a line-of-sight detection process is performed in accordance with a pupil center corneal reflection method. The pupil center corneal reflection method is used to calculate a line-of-sight vector representing the orientation (rotation angle) of the eyeball based on an image of the pupil and a Purkinje image included in the captured eyeball image. Thus, the line of sight of the user can be detected.

A display apparatus according to an exemplary embodiment of the present disclosure may include an image capturing apparatus including a light-receiving element. A displayed image on the display apparatus may be controlled based on information about the line of sight of the user obtained from the image capturing apparatus.

Specifically, the display apparatus determines, based on line-of-sight information, a first field-of-view region at which the user gazes and a second field-of-view region other than the first field-of-view region. The first field-of-view region and the second field-of-view region may be determined by the control device of the display apparatus. Alternatively, regions determined by an external control device may be received. In the display region of the display apparatus, the display resolution of the first field-of-view region may be controlled to be higher than the display resolution of the second field-of-view region. In other words, the resolution of the second field-of-view region may be set lower than that of the first field-of-view region.

Artificial intelligence (Al) may be used to determine a first display region and/or a display region with higher priority. The Al may be a model configured to estimate the angle of the line of sight and the distance to an object on the line of sight based on the eyeball image by using training data including eyeball images and the actual directions of sight of the eyeballs in the images. The Al may be included in the display apparatus, may be included in the image capturing apparatus, or may be included in an external apparatus. The Al included in an external apparatus may be suitable for an application to smartglasses further including an image capturing apparatus that captures an image of the outside. The smartglasses are configured to display information about the captured image of the outside in real time.

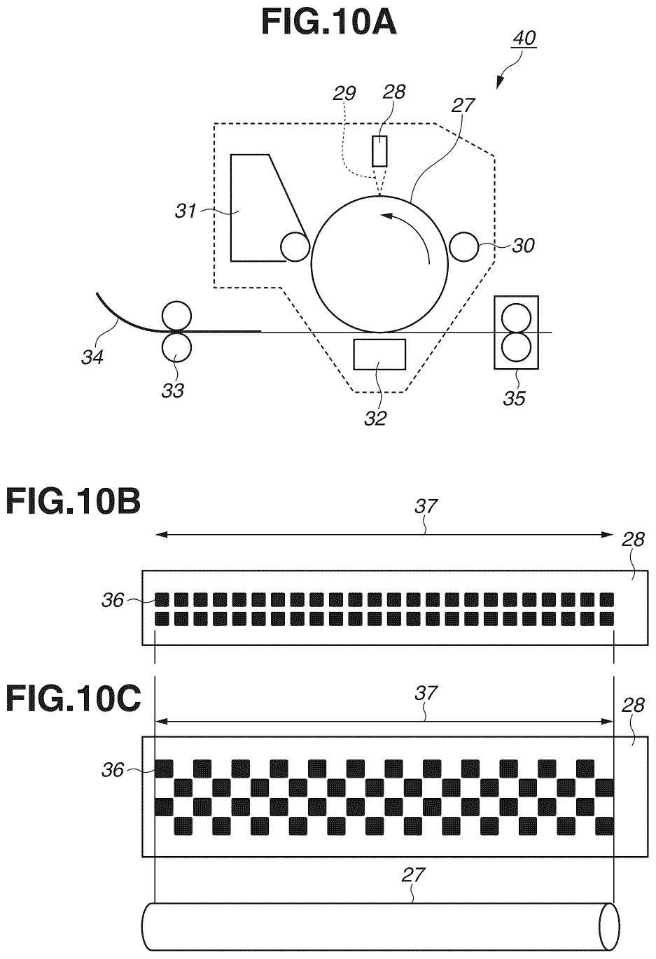

FIG. 10A is a schematic view illustrating an example of an image forming apparatus according to an exemplary embodiment. An image forming apparatus 40 is an electrophotographic image forming apparatus, and includes a photosensitive member 27, an exposure light source 28, a charging unit 30, a developing unit 31, a transfer unit 32, conveyance rollers 33, and a fixing unit 35. Light 29 is radiated from the exposure light source 28, and an electrostatic latent image is formed on the surface of the photosensitive member 27. This exposure light source 28 may include the display apparatus according to the present exemplary embodiment. The developing unit 31 includes toner and other components. The charging unit 30 charges the surface of the photosensitive member 27. The transfer unit 32 transfers the developed image onto a recording medium 34. The conveyance rollers 33 convey the recording medium 34. The recording medium 34 is, for example, paper. The fixing unit 35 fixes the image formed on the recording medium 34.

FIGS. 10B and 10C are schematic views each illustrating the exposure light source 28 and also illustrating a state where a plurality of light-emitting portions 36 is arranged on a long substrate. An arrow 37 represents a column direction in which light-emitting elements are arrayed. This column direction matches a rotation axis direction of the photosensitive member 27. This direction can also be referred to as the long-axis direction of the photosensitive member 27. FIG. 10B illustrates a configuration in which the light-emitting portions 36 are arranged along the long-axis direction of the photosensitive member 27. FIG. 10C illustrates a configuration which is different from the configuration illustrated in FIG. 10B and in which the light-emitting portions 36 are arranged in the column direction alternately between a first column and a second column. The light-emitting portions 36 are arranged at different positions in a row direction between the first column and the second column. In the first column, the plurality of light-emitting portions 36 is arranged at intervals. In the second column, the light-emitting portions 36 are arranged at positions corresponding to the spaces between the light-emitting portions 36 in the first column. In other words, the plurality of light-emitting portions 36 is arranged at intervals also in the row direction. An arrangement illustrated in FIG. 10C may also indicate a state where the light-emitting portions 36 are arranged in a lattice, a state where the light-emitting portions 36 are arranged in a staggered manner, which can be paraphrased as a checkered pattern.

As described above, use of an apparatus using an organic light-emitting element according to any one of the foregoing exemplary embodiments makes it possible to stably display images with high image quality for a long period of time.

As described above, the display apparatus according to any one of the foregoing exemplary embodiments has a configuration in which the width of the first region disposed between the metal layer and the peripheral metal layer is less than or equal to twice the film thickness of the peripheral insulating layer, thus reducing an increase in the resistance of the upper electrode. Furthermore, increasing the region disposed in such a manner that the metal layer and the peripheral metal layer are isolated from each other, thus further reducing the possibility of the metal layer and the peripheral metal layer being electrically connected.

According to an aspect of the present disclosure, it is possible to provide a display apparatus capable of reducing an increase in the resistance of the upper electrode.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-209996, filed Dec. 13, 2023, which is hereby incorporated by reference herein in its entirety.

What is claimed is:

1. A display apparatus comprising:
a substrate;
a display region on the substrate; and
a peripheral region near the display region on the substrate,
wherein the display region includes at least a metal layer, an insulating layer, a lower electrode, a light-emitting layer, and an upper electrode in this order from a substrate side,
wherein the peripheral region includes at least a peripheral metal layer and a peripheral insulating layer in this order from the substrate side,
wherein a first region that isolates the metal layer from the peripheral metal layer is disposed between the metal layer and the peripheral metal layer in a plan view with respect to the substrate, and
wherein a width of the first region is less than or equal to twice a film thickness of the peripheral insulating layer in a cross-section passing through the substrate, the display region, and the peripheral region.

2. The display apparatus according to claim 1,
wherein the peripheral metal layer includes a first peripheral metal layer and a second peripheral metal layer, and
wherein, in a plan view with respect to the substrate, the first peripheral metal layer is disposed between the metal layer and the second peripheral metal layer,
the first region is disposed between the metal layer and the first peripheral metal layer, and
a second region that isolates the first peripheral metal layer from the second peripheral metal layer is disposed between the first peripheral metal layer and the second peripheral metal layer.

3. The display apparatus according to claim 2, wherein a width of the second region is less than or equal to twice the film thickness of the peripheral insulating layer in the cross-section passing through the substrate, the display region, and the peripheral region.

4. The display apparatus according to claim 2, wherein the first peripheral metal layer includes a fourth region that connects the first region to the second region.

5. The display apparatus according to claim 2,
wherein the peripheral metal layer further includes a third peripheral metal layer,
wherein, in a plan view with respect to the substrate, the second peripheral metal layer is disposed between the first peripheral metal layer and the third peripheral metal layer, and
wherein a third region that isolates the second peripheral metal layer from the third peripheral metal layer is disposed between the second peripheral metal layer and the third peripheral metal layer.

6. The display apparatus according to claim 5, wherein a width of the third region is less than or equal to twice the film thickness of the peripheral insulating layer in the cross-section passing through the substrate, the display region, and the peripheral region.

7. The display apparatus according to claim 5, wherein the first peripheral metal layer includes a fourth region that connects the first region to the second region.

8. The display apparatus according to claim 7, wherein, in a plan view with respect to the substrate, a width of the fourth region is greater than the width of the first region and is greater than a width of the second region.

9. The display apparatus according to claim 7, wherein a width of the fourth region is more than twice the film thickness of the peripheral insulating layer in the cross-section passing through the substrate, the display region, and the peripheral region.

10. The display apparatus according to claim 5, wherein the second peripheral metal layer includes a fifth region that connects the second region to the third region.

11. The display apparatus according to claim 5,
wherein the first peripheral metal layer includes a fourth region that connects the first region to the second region,
wherein the second peripheral metal layer includes a fifth region that connects the second region to the third region, and
wherein an intersection between the second region and the fourth region does not match an intersection between the second region and the fifth region in a plan view with respect to the substrate.

12. The display apparatus according to claim 5, wherein the first peripheral metal layer and the second peripheral metal layer include a plurality of peripheral metal layers,
and the plurality of peripheral metal layers is arranged in a staggered manner.

13. The display apparatus according to claim 1, wherein the display region includes an organic light-emitting element.

14. The display apparatus according to claim 1,
wherein the display region includes at least a first pixel and a second pixel,
wherein each of the first pixel and the second pixel includes an organic light-emitting element, and
wherein the insulating layer included in the first pixel and the insulating layer included in the second pixel have different film thicknesses.

15. The display apparatus according to claim 14,
wherein the display region further includes a third pixel,
wherein the third pixel includes the organic light-emitting element, and
wherein the insulating layer included in the first pixel, the insulating layer included in the second pixel, and the insulating layer included in the third pixel have different film thicknesses.

16. The display apparatus according to claim 13, wherein the organic light-emitting element includes an optical resonator structure.

17. The display apparatus according to claim 1,
wherein the peripheral metal layer includes a first metal layer and a first layer different from the first metal layer, and
wherein a reflectance of the first metal layer is higher than a reflectance of the first layer.

18. The display apparatus according to claim 1,
wherein the metal layer includes a second metal layer and a second layer different from the second metal layer, and
wherein a reflectance of the second metal layer is higher than a reflectance of the second layer.

19. The display apparatus according to claim 1,
wherein an interlayer insulating layer is disposed over the substrate, and
wherein the metal layer and the peripheral metal layer are disposed over the interlayer insulating layer.

20. A photoelectric conversion apparatus comprising:
an image sensor configured to receive light; and
a display unit configured to display an image captured by the image sensor,
wherein the display unit serves as the display apparatus according to claim 1.

21. An electronic apparatus comprising:
a display unit including the display apparatus according to claim 1; and
a housing including the display unit; and
a communication unit disposed on the housing and configured to communicate with an external apparatus.

22. A wearable device comprising:
a display unit including the display apparatus according to claim 1;
an optical system configured to collect light of the display unit; and
a control device configured to control an operation of the display unit.
